(19) United States
(12) Patent Application Publication
(10) Pub. No.: US 2006/0289986 A1
(43) Pub. Date: Dec. 28, 2006

(54) In-package connection between integrated circuit dies via flex tape

(76) Inventors: Vadim Sherman, Scottsdale, AZ (US); Lesley A. Polka, Chandler, AZ (US)

Correspondence Address: BUCKLEY, MASCHOFF, TALWALKAR LLC, 5 ELM STREET, NEW CANAAN, CT, 06840, US

(21) Appl. No.: 11/168,890

(22) Filed: Jun. 27, 2005

(51) Int. Cl. H01L 23/12

(52) U.S. Cl. 257/704

(57) ABSTRACT

An integrated circuit (IC) package includes a package substrate and a cap attached to the package substrate. The package substrate and the cap define a space therebetween. The IC package also includes a section of flex tape housed in the space defined by the cap and the package substrate.

### BACKGROUND

It is customary to package an integrated circuit (IC) die within a structure (known as an IC package) that includes a package substrate on which the IC die mounted and a cap which is attached to the package substrate to protect the IC die from above. Typically the package substrate has traces formed therein (sometimes several layers of traces) to route signal paths from the die to contacts provided on the bottom surface of the package substrate. The packaged die is then mounted to a circuit board and is connected to traces in the board via the contacts on the bottom of the package substrate.

So-called “system in package” arrangements have been proposed in which two or more IC dies are housed within a single IC package. In these arrangements, interconnections between the IC dies within the package may be made via traces in the substrate package. However, if a considerable number of such interconnections are required, it may be necessary to lay out the traces in the package substrate with an increased number of layers and/or with increased density. This in turn may increase the cost of manufacture of the package substrate.

### BRIEF DESCRIPTION OF THE DRAWINGS

FIG. 1 is a schematic side view of an integrated circuit package provided according to some embodiments.

FIG. 2 is a schematic side cross-sectional view of the IC package of FIG. 1.

FIG. 3 is a schematic side cross-sectional view of an IC package according to some other embodiments.

FIG. 4 is a schematic side cross-sectional view of an IC package according to still other embodiments.

FIG. 5 is a schematic isometric view of the IC package of FIG. 1 with the cap thereof removed.

FIG. 6 is a flow chart that illustrates an example process for manufacturing the IC package of FIGS. 1, 2 and 5.

FIG. 7 is a block diagram of a computer system according to some embodiments that includes an IC package of one of the preceding drawings.

### DETAILED DESCRIPTION

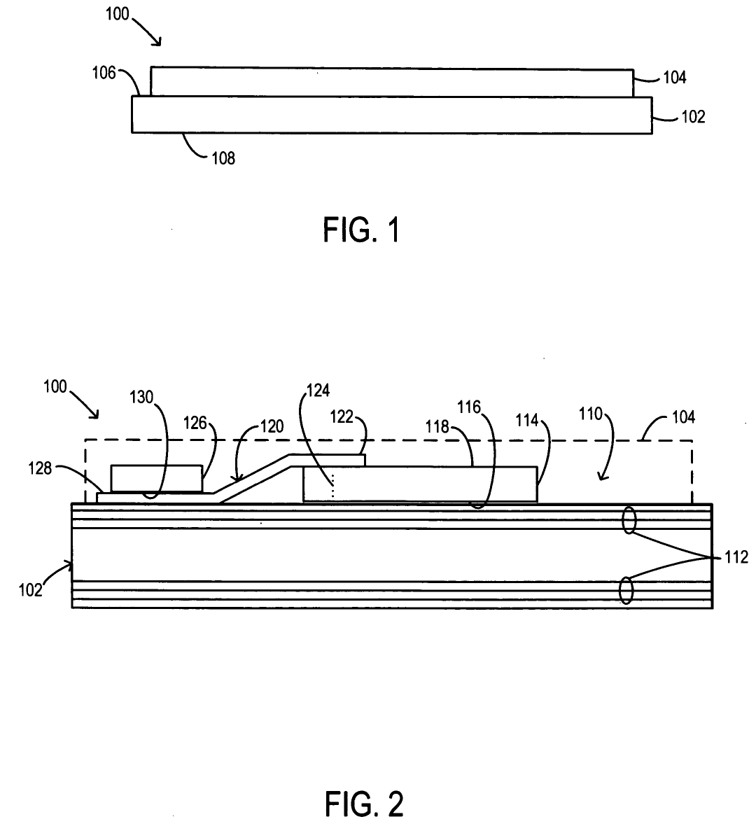

FIG. 1 is a schematic side view of an integrated circuit package 100 provided according to some embodiments. The IC package 100 includes a package substrate 102 and a cap 104 that is attached to the top surface 106 of the package substrate 102. The cap 104 may be, for example, of the type known as an integrated heat spreader (IHS). (To simplify the drawing, contacts that may be present on the bottom surface 108 of the package substrate 102 are not shown.)

FIG. 2 is a schematic side cross-sectional view of the IC package 100. In the view of FIG. 2, the cap 104 is shown in phantom. It will be noted that a space 110 is defined between the package substrate 102 and the cap 104. Traces which are included in the package substrate 102 are schematically indicated at 112. (The number of layers of traces may be more or fewer than the six layers implied by the drawing.)

The IC package 100 also includes an integrated circuit die 114 mounted on the package substrate 102 in the space 110 between the cap 104 and the package substrate 102. The IC die 114 may, for example, be a microprocessor die or another type of IC die which has a large pin count. The IC die 114 may be mounted on the package substrate 102 in accordance with the conventional “flip chip” technique, for example, such that the front side 116 of the IC die 114 faces toward the package substrate 102. (It will be understood that the “front” side 116 of the IC die is the side on which the integrated circuitry is formed.) The back side 118 of the IC die 114 thus faces away from the package substrate 102.

The IC package 100 also includes a section 120 of flex tape. As used herein and in the appended claims, “flex tape” refers to a flexible sheet or strip which contains one or more metal conductive paths therein. The flex tape section 120 is present in the space 110 defined between the package substrate 102 and the cap 104. The flex tape section 120 has an end 122 which is coupled to the back side 118 of the IC die 114. The IC die 114 has one or more through-chip vias (schematically represented at 124) to provide one or more signal paths between the flex tape section 120 and the integrated circuitry on the front side 116 of the IC die 114. One or more conductors in the flex tape section 120 may be solder-connected to one or more conductive paths in the through-chip vias 124 of the IC die 114.

In addition, the IC package 100 includes another IC die 126 mounted in the space 110 defined between the package substrate 102 and the cap 104. The IC die 126 may, for example, be a memory device (e.g., a flash memory) or another type of IC die which has a relatively small pin count. The IC die 126 is supported on the substrate package 102 with an end 128 of the flex tape section 120 sandwiched between the IC die 126 and the package substrate 102. Contacts (not separately shown) on the front side 130 of the IC die 126 are conductively coupled (e.g., by solder) to conductors in the flex tape section 120 such that the flex tape section 120 provides one or more signal paths between the IC die 114 and the IC die 126.

Because one or more signal paths between the dies 114, 126 are provided by the flex tape section 120, the number of signal paths to be provided between the dies 114, 126 by the traces 112 in the package substrate 102 may be reduced or eliminated. Consequently, the number of traces in the package substrate 102 may be reduced, so that a package substrate having fewer layers of traces and/or less dense traces may be employed. Thus the cost of manufacture of the package substrate may be reduced.

Also, the flex tape section, being housed within the structure of the IC package, may be protected from potential damage that may occur in conventional usage of flex tape to provide connections from one IC package to another IC package.

The IC package 100 may also include a thermal interface material (TIM), which is not shown, to thermally couple the back side 118 of the IC die 114 to the cap (IHS) 104. The TIM may cover substantially all of the back side 118 of the IC die 114, omitting only the relatively small portion of the back side 118 to which the end 122 of the flex tape section 120 is coupled.

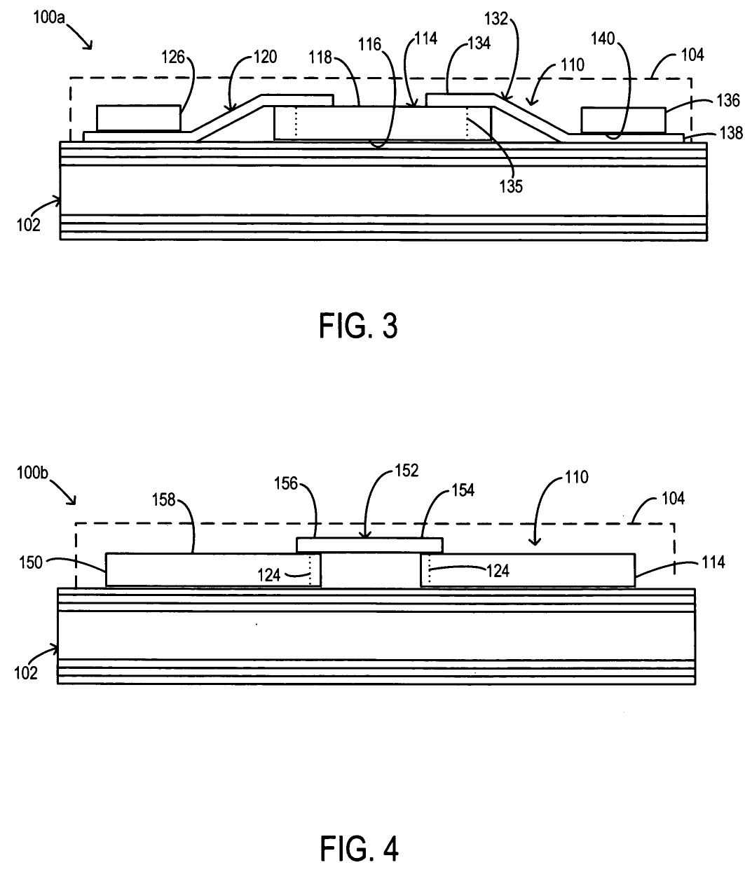

FIG. 3 is a schematic side cross-sectional view of an IC package 100a according to some other embodiments. The IC package 100a may include all of the components described above in connection with FIG. 2. In addition, the IC package 100a includes another section 132 of flex tape. The flex tape section 132 is present in the space 110 defined between the package substrate 102 and the cap 104. The flex tape section 132 has an end 134 which is coupled to the back side 118 of the IC die 114. The IC die 114 has one or more additional through-chip vias (schematically represented at 135) to provide one or more signal paths between the flex tape section 132 and the integrated circuitry on the front side 116 of the IC die 114.

Also, the IC package 100a includes a third IC die 136 mounted in the space 110 defined between the package substrate 102 and the cap 104. The IC die 136 may, for example, be another type of IC die which has a relatively small pin count. The IC die 136 is supported on the substrate package 102 with an end 138 of the flex tape section 132 sandwiched between the IC die 136 and the package substrate 102. Contacts (not separately shown) on the front side 140 of the IC die 136 are conductively coupled to conductors in the flex tape section 132 such that the flex tape section 132 provides one or more signal paths between the IC die 114 and the IC die 136.

In some embodiments, there may be more than three IC dies inside the IC package, and/or there may be more than two sections of flex tape interconnecting the IC dies. Some interconnections between IC dies inside the IC package may be provided by traces in the package substrate 102.

FIG. 4 is a schematic side cross-sectional view of an IC package 100b according to still other embodiments.

Like the previous embodiments, the IC package 100b includes the package substrate 102 and the cap 104 which define the space 110 therebetween. The IC package 100b also includes IC dies 114, 150, both contained in the space 110 and mounted on the package substrate 102. Both of the IC dies 114, 150 may have relatively high pin counts.

The IC package 100b also includes a section 152 of flex tape contained within the space 110. The flex tape section 152 has one end 154 coupled, as before, to the back side 118 of the IC die 114, and its other end 156 coupled to the back side 158 of the IC die 150. Each IC die 114, 150 has one or more through-chip vias 124 to couple the flex tape section 152 to the respective integrated circuitry on the front sides of the IC dies. Thus the flex tape section 152 provides one or more signal paths between the IC dies 114, 150.

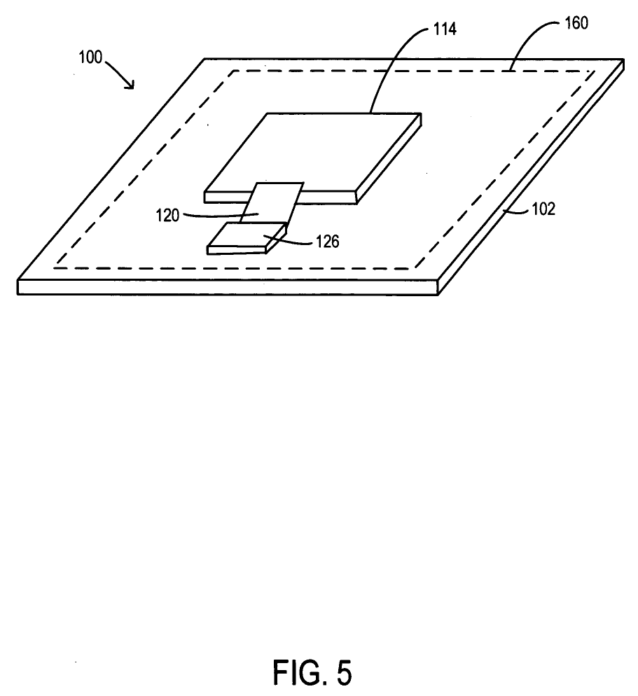

FIG. 5 provides an isometric view of the IC package 100 (FIG. 2) with the cap removed. Dashed outline 160 indicates the locus where the cap is joined to the package substrate 102. It will be appreciated that the cap and the package substrate 102 may completely surround, thus providing substantial protection for, the internal components of the IC package such as the IC dies 114, 126 and the flex tape section 120.

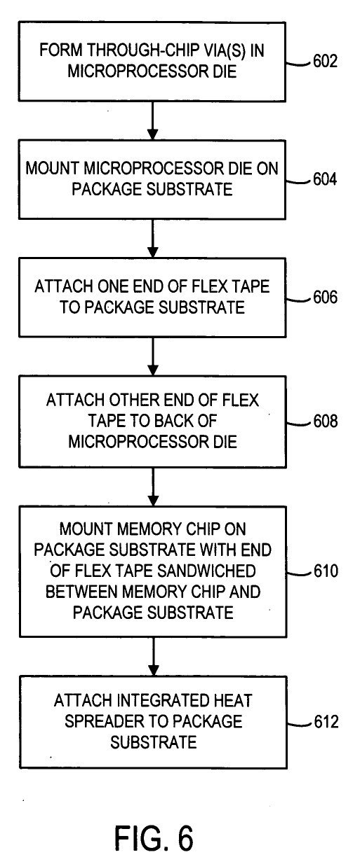

FIG. 6 is a flow chart that illustrates an example process that may be employed in accordance with some embodiments to manufacture an IC package like that illustrated in FIG. 2.

At 602 in FIG. 6, one or more through chip vias are formed in a microprocessor die. At 604 in FIG. 6, the microprocessor die is mounted on the package substrate. This may be done in accordance with conventional flip-chip techniques. At 606, one end of a section of flex tape is attached to the package substrate.

At 608, the other end of the flex tape section if attached to the back side of the microprocessor die, in such a manner as to conductively couple one or more conductors in the flex tape section with the conductors in one or more of the through-chip vias formed through the microprocessor die. Consequently, the conductors in the flex tape section are operatively coupled to the microprocessor circuitry formed on the front side of the microprocessor die.

At 610 a memory IC die is mounted on the package substrate with the first end of the flex tape section sandwiched between the memory device and the package substrate, and so that circuitry on the front side of the memory device (i.e., the side facing toward the package substrate) is conductively coupled to one or more conductors in the flex tape section. As a result, at least some conductive paths between the memory device and the microprocessor are provided by the flex tape section. In some embodiments, all connections to the memory device are by way of the flex tape section.

At 612, a cap (e.g., an IHS) is attached to the package substrate to close the package and to protect the microprocessor, the memory device and the flex tape section during further manufacturing stages, handling, shipment, etc.

The process described in connection with FIG. 6 may be varied to produce other embodiments of the IC package. For example, the process may include attaching one end of a second flex tape section to the back side of the microprocessor and sandwiching the other end of the second flex tape section between a third IC die and the package substrate to interconnect the third IC die and the microprocessor by the second flex tape section. As another example, two IC dies may be mounted directly (e.g., in flip chip fashion) on the package substrate, and then the back side of the two IC dies may be coupled by a flex tape section.

The processes as described herein and in the appended claims are not meant to imply a fixed order of performing the process stages; rather, the process stages may be performed in any order that is practicable.

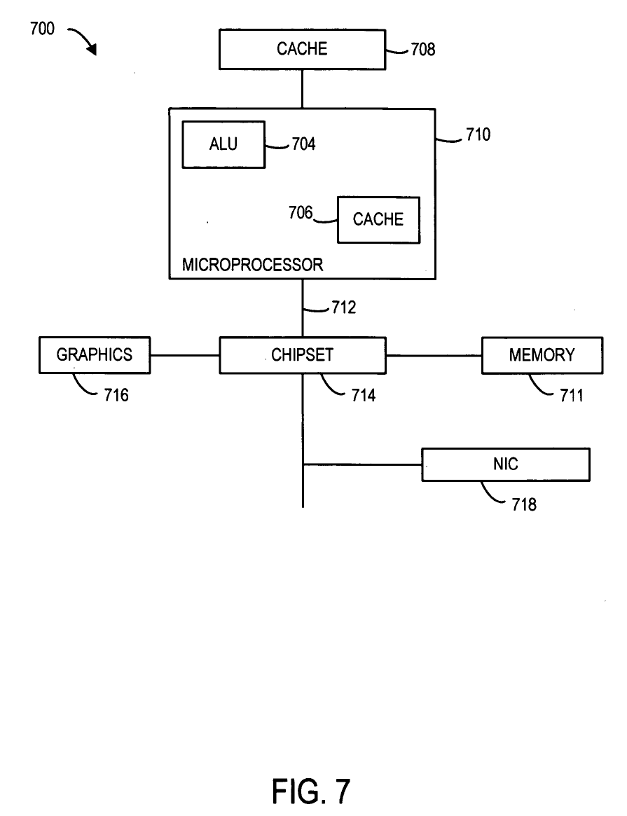

FIG. 7 is a block diagram of a system that may include a microprocessor die 710 that is packaged in an IC package (not separately shown in FIG. 7) of a type described hereinabove. The die 710 includes many sub-blocks, such as an Arithmetic Logic Unit (ALU) 704 and an on-die cache 706. The microprocessor on die 710 may also communicate to other levels of cache, such as off-die cache 708. Higher memory hierarchy levels, such as system memory 711, may be accessed via a host bus 712 and a chipset 714. In addition, other off-die functional units, such as a graphics accelerator 716 and a Network Interface Controller (NIC) 718, to name just a few, may communicate with the microprocessor on die 710 via appropriate busses or ports.

The chipset 714 may, for example, be packaged together with the microprocessor die 710 or may alternatively be located outside of the package in which the microprocessor die 710 is housed. Some or all of the other components shown in FIG. 7 may or may not be housed in the same package with the microprocessor die 710. The system architecture shown in FIG. 7 is exemplary; other system architectures may be employed.

The several embodiments described herein are solely for the purpose of illustration. The various features described herein need not all be used together, and any one or more of those features may be incorporated in a single embodiment. Therefore, persons skilled in the art will recognize from this description that other embodiments may be practiced with various modifications and alterations.

What is claimed is:

1. An integrated circuit (IC) package, comprising:
a package substrate; and
a cap attached to said package substrate;
said package substrate and said cap defining a space therebetween, said IC package further comprising:
a section of flex tape housed in said space defined by said cap and said package substrate.

2. The IC package of claim 1, further comprising:
a first IC die supported on said package substrate; and
a second IC die supported on said package substrate;
wherein said section of flex tape provides a signal path between said first and second IC dies.

3. The IC package of claim 2, wherein:
a first end of said section of flex tape is sandwiched between said first IC die and said package substrate; and
a second end of said section of flex tape is coupled to a first side of said second IC die, said first side of said second IC die facing away from said package substrate.

4. The IC package of claim 3, wherein:
said second IC die has at least one via formed therethrough, said at least one via to provide a signal path between said second end of said section of flex tape and an IC formed on a second side of said second IC die, said second side of said second IC die facing toward said package substrate.

5. The IC package of claim 4, further comprising:
a third IC die supported on said package substrate; and
a second section of flex tape;
wherein:
a first end of said second section of flex tape is sandwiched between said third IC die and said package substrate; and
a second end of said second section of flex tape is coupled to said first side of said second IC die.

6. The IC package of claim 2, wherein:
a first end of said section of flex tape is coupled to a first side of said first IC die, said first side of said first IC die facing away from said package substrate; and
a second end of said section of flex tape is coupled to a first side of said second IC die, said first side of said second IC die facing away from said package substrate.

7. A method comprising:
mounting a first integrated circuit (IC) die on a package substrate;
mounting a second IC die on the package substrate; and
coupling a section of flex tape to said first IC die and to said second IC die.

8. The method of claim 7, wherein said section of flex tape provides a signal path between said first and second IC dies.

9. The method of claim 8, wherein said coupling and said mounting said first IC die include sandwiching a first end of said section of flex tape between said first IC die and said package substrate.

10. The method of claim 9, further comprising:
mounting a third IC die on the package substrate; and
coupling a second section of flex tape to said second IC die and to said third IC die.

11. The method of claim 10, wherein said second section of flex tape provides a signal path between said second IC die and said third IC die.

12. The method of claim 11, wherein said coupling the second section of flex tape and mounting the third IC die include sandwiching a first end of said second section of flex tape between said third IC die and said package substrate.

13. The method of claim 7, further comprising:
attaching a cap to said package substrate to enclose said first and second IC dies and said section of flex tape.

14. The method of claim 7, wherein said coupling includes coupling at least one conductor in said section of flex tape to at least one through-chip via in said second IC die.

15. A system comprising:
an integrated circuit (IC) package having a microprocessor die housed therein; and
a chipset in communication with said microprocessor die;
wherein said IC package includes:
a package substrate on which said microprocessor die is mounted;
a cap attached to said package substrate and defining a space with said package substrate, said microprocessor die housed in said space;
a second IC die supported on said package substrate and housed in said space; and
a section of flex tape which provides a signal path between said microprocessor die and said second IC die.

16. The system of claim 15, wherein:
a first end of said section of flex tape is sandwiched between said second IC die and said package substrate; and
a second end of said section of flex tape is coupled to a first side of said microprocessor die, said first side of said microprocessor die facing away from said package substrate.

17. The system of claim 16, wherein:
said microprocessor die has at least one via formed therethrough, said at least one via to provide a signal path between said second end of said section of flex tape and circuitry formed on a second side of said microprocessor die, said circuitry comprising a microprocessor, said second side of said microprocessor die facing toward said package substrate.

18. The system of claim 17, wherein:
said IC package further includes:
a third IC die supported on said package substrate; and
a second section of flex tape; and
a first end of said second section of flex tape is sandwiched between said third IC die and said package substrate; and
a second end of said second section of flex tape is coupled to said first side of said microprocessor die.

19. The system of claim 15, wherein:
a first end of said section of flex tape is coupled to a first side of said microprocessor die, said first side of said microprocessor die facing away from said package substrate; and
a second end of said section of flex tape is coupled to a first side of said second IC die, said first side of said second IC die facing away from said package substrate.
